(19) United States
(12) Patent Application Publication
(10) Pub. No.: US 2003/0197285 A1
(43) Pub. Date: Oct. 23, 2003

(54) High density substrate for the packaging of integrated circuits

(75) Inventors: Jan I. Strandberg, San Jose, CA (US); Richard Scott Trevino, San Jose, CA (US); Thomas B. Blount, San Jose, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Kulicke & Soffa Investments, Inc., Wilmington, DE

(21) Appl. No.: 10/128,813

(22) Filed: Apr. 23, 2002

(51) Int. Cl. H01L 23/053; H01L 23/12; H01L 23/34; H01L 23/48; H01L 23/52; H01L 29/40

(52) U.S. Cl. 257/778; 257/737; 257/738; 257/700; 257/774; 257/758; 257/712; 257/704

(57) ABSTRACT

A package for mounting an integrated circuit die. In one embodiment the package comprises a metal substrate having first and second primary opposed surfaces and an aperture formed therebetween. A flexible thin film interconnect structure having bottom and top opposing surfaces is formed over the first primary surface of the metal substrate and over the aperture such that a first region of the bottom surface is in direct contact with the first surface of the metal substrate and a second region of the bottom surface is opposite the aperture. Within the second region of the bottom surface are a first plurality of exposed bonding pads having a first pitch appropriate for attaching the integrated circuit die to package. The top surface of the flexible thin film interconnect structure includes a second plurality of exposed bonding pads having a pitch greater than the first pitch.

### CROSS-REFERENCE TO RELATED APPLICATIONS

This application is being filed concurrently with U.S. patent application Ser. No. ______, by Jan I. Strandberg et al., entitled “Method for Manufacture of a High Density Substrate for the Packaging of Integrated Circuits” (Attorney Docket No. 016301-003600US). The disclosure of the 016301-003600US application is incorporated herein by reference in its entirety for all purposes.

### BACKGROUND OF THE INVENTION

The present invention relates to the packaging of integrated circuits. Some specific embodiments of the invention pertain to an integrated circuit (IC) package that has a metal substrate and a flexible thin film interconnect structure upon which the IC is mounted and a method for manufacturing the same.

The semiconductor industry continues to produce integrated circuits of increasing complexity and increasing density. The increased complexity of some of these integrated circuits has in turn resulted in an increased number of input/output pads on the circuit chips. At the same time, the increased density of the chips has driven the input/output pad pitch downward. The combination of these two trends has been a significant increase in the connector pin wiring density needed to connect the chips to packages that interface with the outside world and/or interconnect the chips to other integrated circuit devices.

One technology that has been used to meet such high density packaging demands combines flip chip and ball grid array (BGA) technologies to produce relatively small chip scale packages that have a relatively high lead count. According to one conventional method for creating flip chip BGA packages (FCBGA), a thin film interconnect structure is formed over one side of a laminate substrate, such as a printed circuit board (PCB), that has through holes that provide electrical connections from one side of the substrate to the other. A plurality of high density flip chip bonding pads are formed in the thin film interconnect structure and solder bumps are affixed to an integrated circuit which is then flipped upside down such that the solder bumps are brought into contact with their corresponding high density bonding pads. The solder balls are then reflowed to connect the integrated circuit to the thin film side of the PCB substrate.

Underfill, such as a thermo-set epoxy, is then dispensed in the gap between the integrated circuit and the substrate. The underfill is then cured by heating the substrate and integrated circuit to an appropriate curing temperature. Next, the assembly is cooled down and solder balls are attached to BGA bonding pads formed the other side of the substrate to complete the packaging structure. Circuits connecting the BGA pads on the one side of the substrate to the high density flip chip pads (and therefore to the attached die) on the other side of the substrate are made through the plated through holes.

In order to achieve the high density interconnections desirable for some integrated circuit die packaging solutions, accurate registration of the photolithography involved in the formation of the thin film interconnect structure is critical. One problem with this conventional approach is that the laminate substrate over which the thin film layers are formed is subject to slight mechanical changes when subjected to humidity, different temperatures and other environmental factors. These slight mechanical changes may interfere with the accuracy of the thin film photolithography process thereby resulting in defective packaging structures.

NEC has developed a FCBGA technology that uses a metal substrate base instead of the traditional PCB laminate base. Using a metal substrate provides better registration accuracy than a traditional PCB or other type of laminate substrate which in turn enables very high density patterning steps to be more accurately used in the thin film interconnect structure formed over the substrate. According to NEC, their technology also is more cost effective than previously employed FCBGA technologies as fewer layers are fabricated and a smaller number of the fabricated layers need to be fine-pitch patterned.

FIGS. 1A-1G are simplified cross-sectional views of a packaging structure formed according to the NEC process. The NEC process forms a thin film interconnect structure over a metal substrate 10. The NEC engineers noted that substrate 10, which may be a stainless steel and copper alloy, should be an easily obtainable material that is suitable for manufacturing to high-tolerance flatness while also being strong enough to resist the pressure toward curvature that is exerted by a resin-film structure formed over the substrate.

As shown in FIG. 1A, the NEC process starts by forming a plurality of BGA pads 12 over metal substrate 10. BGA pads 12 are a three layer stack of gold (12a), nickel (12b) and copper (12c) as shown in FIG. 11B. Next, a thin film interconnect structure 14 is formed over the BGA pads (FIG. 1C). Interconnect structure 14 may include several thin film dielectric layers 16a, 16b and 16c as well as several thin film conductive layers 18a, 18b. Vias 20 interconnect various portions of layers 18a and 18b to each other and to BGA pads 12. Also formed on the upper surface of the thin film interconnect structure 14 are a plurality of flip chip pads 22 that enable bonding of an integrated circuit die 30 as shown in FIG. 1D.

IC die 30 is attached to pads 22 using solder bumps 36. An underfill layer 34 is applied between the bottom of IC 30 and the top of thin film interconnect structure 14 in order to reduce the stress and fatigue on the solder balls during thermal cycling.

Referring to FIG. 1E, next a stiffener 38 and a lid 40 are added. In order for stiffener 38 to be adequately secured to the thin film interconnect structure 14 formed over substrate 10, a conductive adhesive (not shown) is applied between the stiffener and thin film structure at interface 39. Also, a thermal grease 42 may be placed over integrated circuit 30 before lid 40 is attached. After stiffener 38 and lid 40 are attached, metal substrate 10 is removed using a wet etch process to expose the BGA pads 12 as shown in FIG. 1F. Finally, the structure may be completed by attaching a heat spreader (not shown) to lid 40 and forming BGA solder balls 44 (shown in FIG. 1G) on pads 12 as appropriate.

While the above described process seems to be an improvement as compared to the conventional FCBGA technology described above. It suffers from a number of drawbacks. First, integrated circuit 30 is attached to thin film interconnect structure 14 before the thin film structure can be adequately tested for shorts using conventional electrical testing techniques, e.g., contact testing. This is because IC die 30 is attached prior to removing metal substrate 10 by the wet etch process. Forming thin film interconnect structure 14 over a conductive substrate, such as metal substrate 10, shorts the various circuits formed in the interconnect structure until the conductive substrate is removed. Thus, if a short or similar defect exists in thin film structure 14, integrated circuit 30, which may be quite expensive, may be lost resulting in a lower yield process unless specialized optical or other testing techniques are employed.

Another drawback with the NEC approach is that it would most likely require that the ground reference plane for the interconnect package be formed in the relatively expensive thin film structure. While it is possible to use a metal stiffener 38 as the ground reference plane, all conductive adhesives known to the present inventors that may be used to attach the stiffener to thin film structure 14 would act as a high ohmic reference plane that would have a resistivity at least one or two orders of magnitude higher than copper. This approach would thus greatly slow down signals passing through the interconnect structure making it impractical for high speed devices.

Thus, while the NEC FCBGA package structure just described may be an improvement over some other integrated circuit packaging structures, new and improved integrated circuit packaging techniques and structures are desirable.

### BRIEF SUMMARY OF THE INVENTION

Embodiments of the present invention pertain to packaging structures and semiconductor devices that include a metal substrate and a flexible, overlying thin film interconnect structure. The packaging structure can be tested for both shorts and opens in the thin film interconnect structure using standard testing techniques prior to attaching an integrated circuit die to the thin film interconnect structure.

According to one embodiment of the invention, a package for mounting an integrated circuit die is provided. The package includes a metal substrate having first and second primary opposed surfaces and an aperture formed therebetween. A flexible thin film interconnect structure having bottom and top opposing surfaces is formed over the first primary surface of the metal substrate and over the aperture such that a first region of the bottom surface is in direct contact with the first surface of the metal substrate and a second region of the bottom surface is opposite the aperture. Within the second region of the bottom surface are a first plurality of exposed bonding pads having a first pitch appropriate for attaching the integrated circuit die to package. The top surface of the flexible thin film interconnect structure includes a second plurality of exposed bonding pads having a pitch greater than the first pitch. In some embodiments the metal substrate is a copper substrate.

In one embodiment the flexible thin film interconnect structure comprises a plurality of thin film dielectric layers having an elongation percentage of at least 30 percent. In another embodiment the elongation percentage of the dielectric layers in the flexible thin film interconnect structure is between 40-50 percent. In still other embodiments the aperture is defined by a sidewall that is angled or curved inward where the sidewall contacts the overlying flexible thin film interconnect structure.

In another embodiment, a semiconductor device is provided. The semiconductor device comprises a metal substrate having first and second opposing surfaces and an aperture formed therebetween and a flexible thin film interconnect structure formed over the first surface of the metal substrate and over the aperture. The flexible thin film interconnect structure has bottom and top opposing surfaces and a plurality of thin film conductive layers and a plurality of thin film dielectric layers formed between the bottom and top surfaces, the thin film dielectric layers having an elongation percentage of at least 30 percent. The bottom surface of the thin film interconnect structure includes a first region in direct contact with the first surface of the metal substrate and a second region that overlies the aperture in the metal substrate. A first plurality of bonding pads spaced at an integrated circuit pitch are formed on the bottom surface of the thin film interconnect structure within the aperture of the metal substrate and a second of bonding pads spaced at a package pitch are formed on the top surface of the thin film interconnect structure. The semiconductor device also includes an integrated circuit die attached to the first plurality of bonding pads within the aperture and a lid attached to the second surface of the metal substrate such that the lid encloses the integrated circuit die within the aperture.

These and other embodiments of the invention, as well as its features and some potential advantages, are described in more detail in conjunction with the text below and attached figures.

### BRIEF DESCRIPTION OF THE DRAWINGS

FIGS. 1A-1G are simplified cross sectional views of a packaging structure formed according to a previously known technique;

FIG. 2 is a flow chart illustrating the steps associated with fabricating a packaging structure according to one embodiment of the present invention;

FIGS. 3A-3G are simplified cross sectional views of a packaging structure formed according to the process set forth in FIG. 2;

FIG. 4 is a simplified top plan view of substrate 110 shown in FIGS. 3A and 3B having a plurality of bonding pads formed over a region of the substrate where an integrated circuit die is to be attached to a thin film interconnect layer formed over the substrate and the bonding pads; and

FIGS. 5A-5C are simplified cross-sectional views of packaging structures that may be formed according to embodiments of the present invention.

### DETAILED DESCRIPTION OF THE INVENTION

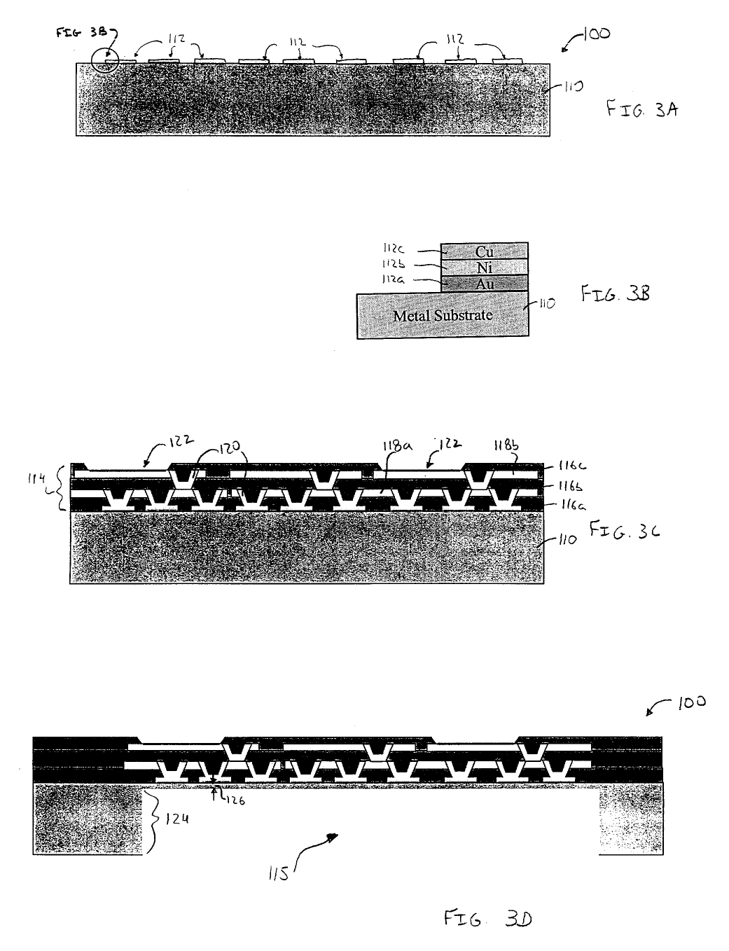

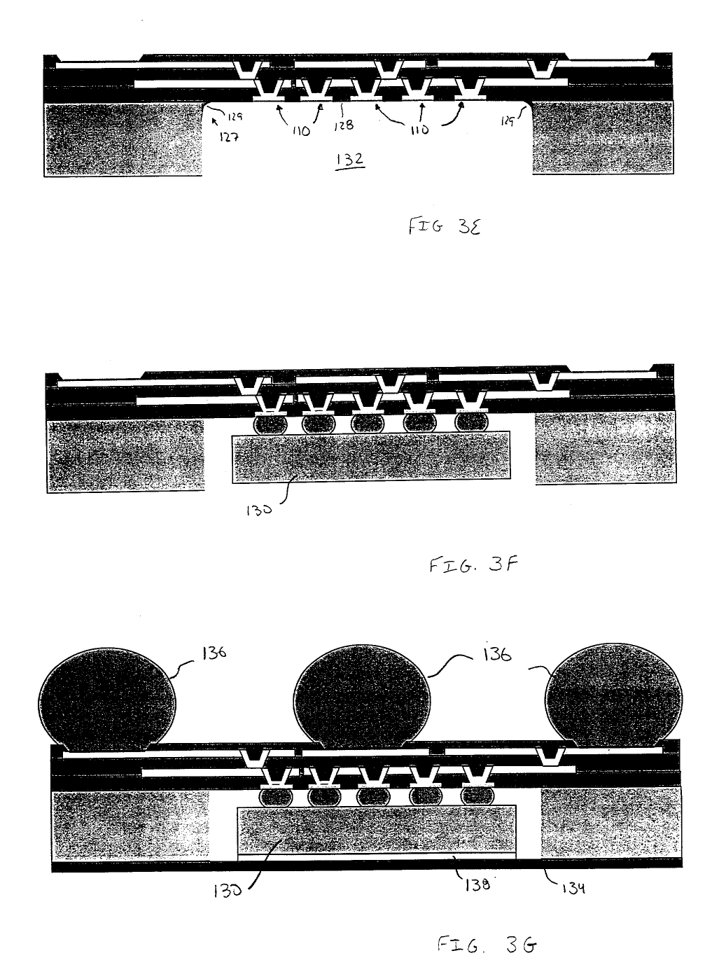

As previously stated, one embodiment of the present invention pertains to a method of forming an integrated circuit package that uses a metal substrate as a base upon which overlying thin film interconnect layers are formed. Unlike the NEC technique that also uses a metal substrate, the method of the invention enables testing of the thin film interconnect structure for both shorts and opens using standard electrical testing techniques prior to attaching a die to the thin film interconnect structure. In order to better appreciate and understand the present invention, reference is made below to FIG. 2, which is a flow chart illustrating the steps associated with fabricating a chip level package according to one embodiment of the invention, and FIGS. 3A-3G, which are simplified cross-sectional views of a chip level package structure at various stages of formation set forth in the flowchart of FIG. 2.

Referring to FIG. 2 and FIG. 3A, the method starts by providing a metal substrate 110 (FIG. 2, step 50), which will be part of a final packaging structure 100 that is to be formed. In one embodiment substrate 110 is a copper substrate but in other embodiments substrate 110 can be made from any appropriate metal material that can be milled and/or etched to form a pocket in which an integrated circuit die can be positioned as discussed below. Substrate 110 can be any appropriate thickness. In some embodiments, substrate 110 is ground in step 50 to a thickness that is approximately equal to the thickness of the silicon die to be packaged on substrate 110 combined with the die's associated bonding pads and solder bumps (bump height). In one example, substrate 110 may be purchased as a copper plate from an appropriate materials supply company to have an initial thickness of 800±25 microns and be ground to a thickness of 600 microns in step 50. Step 50 may also include cleaning the metal substrate to remove grease and/or other contaminants and oxidizing or roughening the surface to improve the adhesion of layers subsequently formed over the substrate.

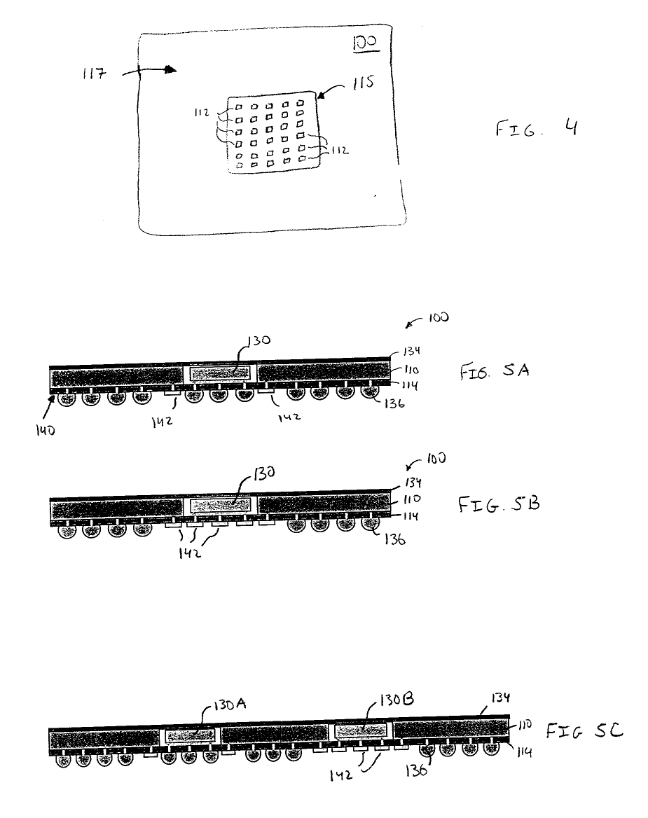

Next, a plurality of flip chip pads 112 are formed over substrate 110 (FIG. 2, step 52). Referring to FIG. 4, which is a simplified top plan view of substrate 110, pads 112 are formed over a region 115 of substrate 110 that is subsequently etched away in step 56 so that an integrated circuit die can be attached to pads 112. In one embodiment pads 112 are formed by depositing and patterning an appropriate photoresist material over substrate 110 and then plating one or more layers of metal over the substrate by applying a plating current to the substrate. Referring to FIG. 3B, in one particular embodiment pads 112 are a three layer structure that includes a bottom layer 112a of gold, a middle nickel layer 112b and an upper copper layer 112c.

Pads 112 may be subsequently used to attach a silicon die or other type of integrated circuit die to the packaging structure. Accordingly, in some embodiments pads 112 are spaced at an IC-pitch of, for example, 150-250 microns. Also, in some embodiments the width of pads 112 is about 40-50% of the pitch.

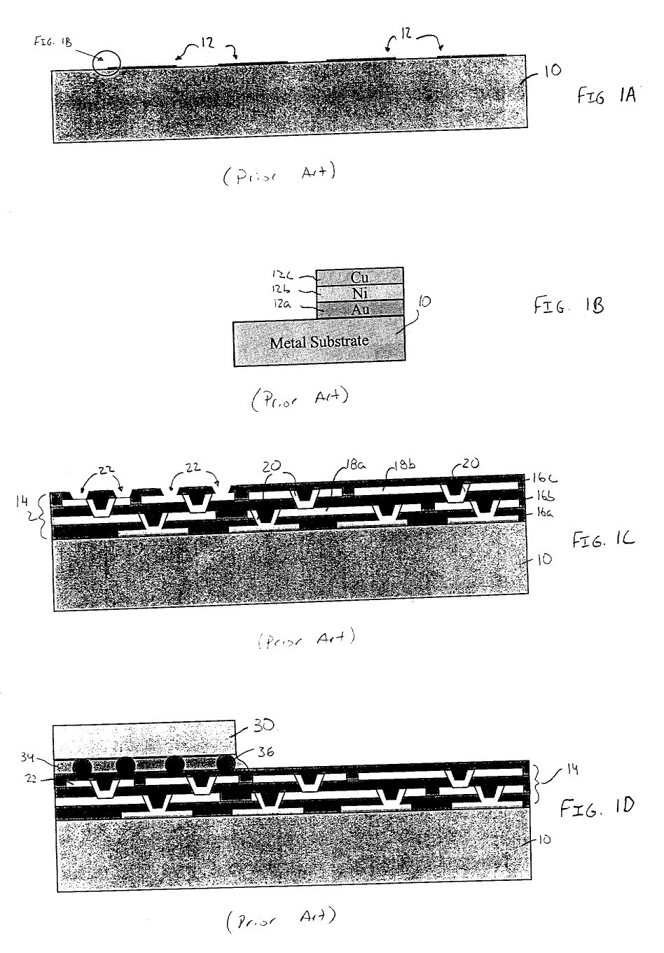

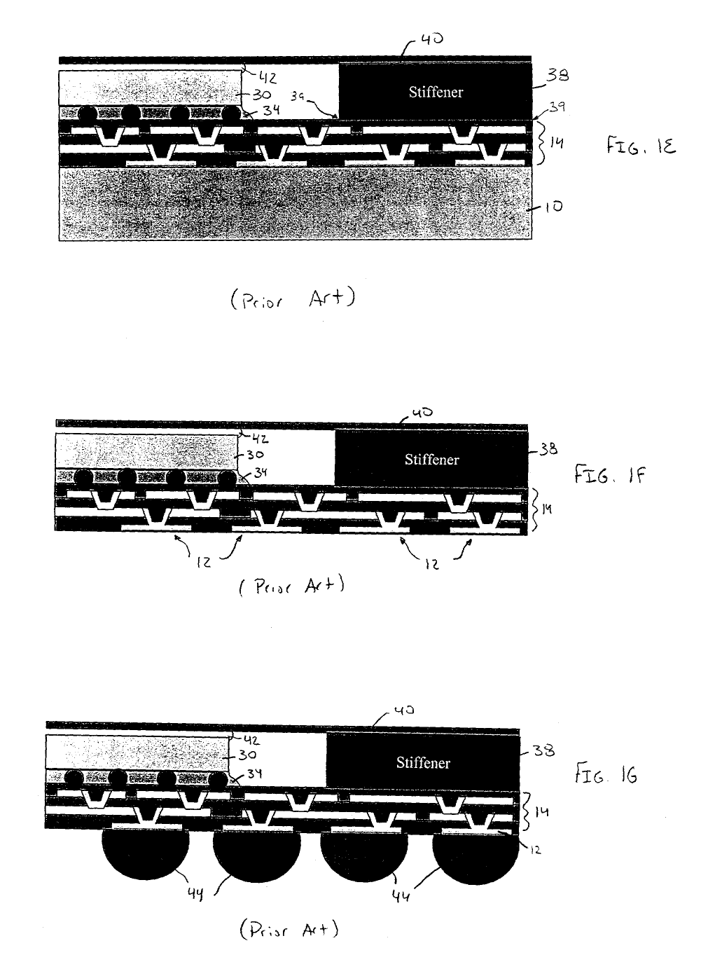

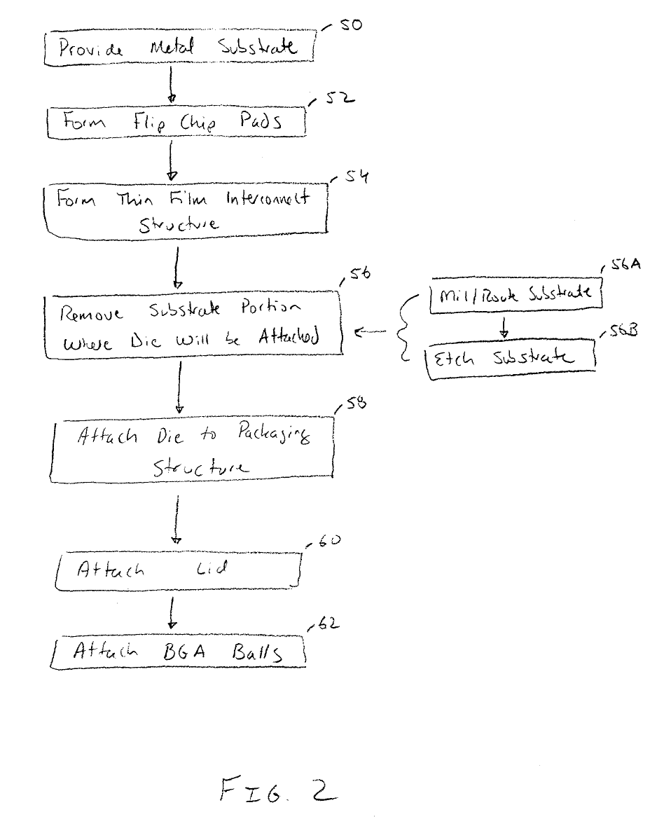

In contrast, pads 12 shown in FIGS. 1A and 1B are for component level connections rather than die level connections. Thus, the pads 12 in FIGS. 1A and 1B are used to connect component level devices through BGA solder bumps 44 as shown in FIG. 1G. The spacing of such BGA level pads is considerably less dense than the spacing of the die level pads. For example, BGA pads are typically spaced at a package-pitch of, for example, 0.5-1.0 mm. Also, the width of such package-pitched pads is typically about 50-60% of their pitch.

Referring to FIG. 1C, next a thin film interconnect structure 114 is formed over substrate 110 and pads 112 (FIG. 2, step 54). Thin film interconnect structure 114 may include alternating dielectric and conductive layers as appropriate to route signal paths and other lines over the packaging structure. Also formed in thin film interconnect structure 114 are pads 122, which in one embodiment are spaced at a package-pitch for component level connections using, for example, BGA solder bumps.

The number of layers in interconnect structure 114 will depend on the application. As an example, packaging structure 100 shown in FIG. 3C includes two signal layers, metal layers 118a and 118b. Layer 118a is separated from pads 112 by a thin film dielectric layer 116a; layers 118a and 118b are separated from each other by a thin film dielectric layer 116b and a thin film dielectric layer 116c covers layer 118b except in the areas where pads 122 are formed. Vias 120 are formed between the various thin film conductive layers 118a, 118b, pads 112 and pads 122.

According to one embodiment of the invention, thin film interconnect layer 114 is a flexible layer after curing. As used herein, being “flexible” means, when separated from substrate 102, interconnect layer 114 can be bent up and down like a piece of copper foil or Scotch tape without much effort. In contrast, a rigid layer, such as a metal layer, cannot be readily bent without the use of considerable force. As will be discussed in more detail below, subsequent processing to packaging structure 100 removes all of substrate 110 in the area 115 where an integrated circuit die is to be attached to pads 112. Thus, at that stage of processing, the portion of layer 114 above area 115 is left unsupported except to the extent that portions of layer 114 are attached to regions 117 of substrate 110 adjacent to region 115.

In embodiments of the invention, interconnect structure 114 is made flexible by using a polymer material that has a relatively high elongation percentage (e.g., over 30 percent) for one or more of the individual dielectric layer(s) within the thin film interconnect structure. In some embodiments, each dielectric layer within the thin film interconnect structure has an elongation percentage of 30 percent or higher. In one particular embodiment, the dielectric layers within interconnect structure 114 have an elongation percentage of between about 40-50 percent.

In some embodiments, the dielectric layers in thin film interconnect structure 114 are formed from a photosensitive polyamide material thereby allowing the formation of vias within the layers using standard photolithography techniques without a special photomask layer. In other embodiments, however, the thin film dielectric layers are a laser ablatable material and the vias may be formed using laser ablation techniques.

Other desirable properties for the thin film dielectric layers according to some embodiments of the invention include a glass transition temperature above 260° C. (the temperature that certain lead-free solder bumps that may be desirable to use are reflowed at as discussed more below), a total halogen content of less than 10 ppm and a tensile strength of at least 100 MPa. One example of a suitable polymer material for layers 116a-116c is CRC-8000 available from Sumitomo Bakelite. CRC-8000 is a polybenzoxasole (PBO) material that is a positive acting, photosensitive polymer. Depending on the material used, certain embodiments of the invention develop and pattern the material after it is deposited and then subsequently cure the material to cross links the polymers and improve the layer's mechanical strength.

In other embodiments, other appropriate elastic polyamides, epoxy-based resins and/or other materials may be used as dielectric layers in the thin film structure. In one embodiment the thin film dielectric layers are formed using a standard spin-on process, while other embodiments may apply the material using spray coating, extrusion or any other appropriate technique for the selected material. Conductive layers 118a and 118b may be formed from any appropriate metal using any appropriate deposition technique. In one example, layers 118a and 118b are copper layers that are formed by an electroplating process. In some embodiments, layers 118a and 118b include multiple layers such as a seed layer and/or a barrier layer.

After the thin film interconnect structure is formed, a portion of substrate 110 is removed forming an aperture 115 that exposes pads 110 as shown in FIGS. 3D and 3E (FIG. 2, step 56). In one embodiment the removal of the portion of substrate 110 thereby forming aperture 115 is a two step process where a first thickness of the substrate is removed in a milling operation (step 56a) and a second thickness is removed in a wet etch process (step 56b). Such an embodiment is illustrated in FIGS. 3D and 3E. As can be seen in FIG. 3D, milling step 56a may remove a majority of the substrate (thickness 124) in area 115 leaving a relatively thin (e.g., 50-150 micron) layer. The remaining thickness 126 of the substrate in area 115 (aperture 115) can then be removed in a wet etch process creating the structure 100 that includes a cavity 132 where the substrate was removed as shown in FIG. 3E. In one embodiment, aperture 115 is shaped similarly to the integrated circuit die that will be subsequently placed within the aperture and attached to interconnect layer 114.

One benefit achieved in some embodiments of the invention is that the wet etching process that removes final thickness 126 of substrate 110 etches material less effectively in the corner areas 127 of the substrate than the flat surface 128. Accordingly, an angled or curved interface 129 may be formed in the corner areas. Such an angled or curved surface serves to reduce stress between the thin film interconnect structure 114 and the remaining portion of substrate 110.

Referring to FIG. 3F, next an integrated circuit die 130 is attached to bonding pads 120 in cavity 132 using a suitable process such as flip chip bonding (step 58). The flip chip or other bonding process will often result in a pressure being applied against the thin film interconnect structure 114. Such pressure may tend to distort and/or stretch the interconnect structure, which in some embodiments is less than 100 microns thick. The flexibility of structure 114, however, helps it withstand such forces.

Optionally, an underfill resin (not shown) may be arranged between die 130 and thin film interconnect structure 114 to improve mounting reliability. When a flip chip bonding technique is used on a rigid substrate, such an underfill resin may help relieve stress and fatigue between the bumps and die associated with the various thermal cycles the packaging structure is subjected to. In embodiments of the invention, such an underfill resin is optional as the relatively high flexibility of the interconnect structure should reduce such stress and fatigue to manageable levels in many embodiments. In certain embodiments of the invention the underfill resin may be useful, however, to protect the die surface from ionic and/or other contamination.

After die 130 is attached, a lid 134 is placed over the die and substrate (step 60) and solder bumps or other appropriate bumps are formed on exposed pads 122 on the side of the thin film interconnect structure opposite that of die 130 as shown in FIG. 3G (step 62). In one embodiment lid 134 is attached to the packaging structure prior to bumps 136 but this is not necessary in other embodiments. Lid 134 is typically a metal lid, e.g., copper, that helps with heat dissipation. Fins (not shown) may be attached to lid 134 to further dissipate heat as appropriate. Also, a thermal grease 138 may be applied to integrated circuit die 130 to help facilitate heat transfer from die 130 to lid 134.

FIG. 5A shows one example of a final chip level package 100 produced by the method depicted in FIG. 2. As shown in FIG. 5A, BGA bumps 136 formed on lower surface 140 of package 100 can be used to connect integrated circuit die 130 to passive components and/or various electronic structures. Also, in some area capacitors 142 and/or other passive components may be formed directly over the BGA pads. FIG. 5B shows that capacitors 142 may be formed over pads 122 so that they are spaced from die 130 by a distance that is approximately equal to the combined thickness of thin film interconnect structure 114 and the flip chip bumps. Such relatively close spacing of the capacitors to the die may reduce the inductance between the die and the capacitors thereby improving the performance (e.g., speed) and efficiency of the package. The lower inductance levels that are achievable using such a design may also lead to fewer capacitors being necessary than if the capacitors were spaced one or more millimeters from the die as is necessary in some previously known FCBGA packages.

In one embodiment of the invention, steps 50 to 56 discussed above are performed at a first location, such as the fabrication facility owned by a manufacturer of chip level packaging structures, and steps 58 to 62 are performed at a second location, such as the semiconductor assembly facility. In another embodiment, the thin film interconnect structure 114 formed over substrate 110 is tested for both open circuits and short circuits using a standard testing procedure such as contact testing between steps 56 and 58 (shown as step 57 in FIG. 2). The testing of step 57 can be done at the chip level package fabrication facility, at the assembly facility or both.

Step 57 is able to test for both open and short circuits prior to the attachment of die 130 by probing appropriate ones of pads 110 and 122 because all of substrate 110 was milled and/or etched away in the area 115 where pads 110 are formed. In contrast, the technique used by NEC discussed with respect to FIGS. 1A-1G cannot test for short circuits using standard industry techniques such as contact testing, because metal substrate 10 shorts the connection between individual ones of pads 12 at the stage of the process when integrated circuit die 30 is attached. Substrate 10 is not removed from the NEC packaging structure until after the die, stiffener and die are attached as shown in FIGS. 1E and 1F. Accordingly, the method of the present invention can avoid the costly mistake of attaching a good die to a defective thin film interconnect structure and thus help improve a manufacturer's yield.

Embodiments of the invention also allow for the use of various lead-free bumps to attach die 130 to substrate 110 and to attach the BGA balls. The reflow temperature for some of these lead-free bumps, which may be made from, for example, an alloy of tin, copper and silver may be above 260° C. It is generally undesirable to heat traditional PCB material to temperatures this high as water molecules absorbed in the laminate structure, underfill material or thin film dielectric layers may cause defects in the laminate material. Metal substrate 110 can readily be heated to temperatures of 260° C. or higher, however.

Also, in some embodiments of the chip level packaging structure of the present invention, substrate 110 may be used as a ground reference plane for packaging structure because thin film interconnect 114 is formed directly on substrate 110 without an intervening adhesive layer. In such a structure, some contact pads may be formed in region 117 (FIG. 4) of substrate 110 which is not removed during step 56. Circuits within the thin film interconnect structure 114 may route the ground signal from substrate 110 through the contact pads to other parts of the interconnect structure 114 and to BGA pads 122 as appropriate. Using substrate 110 as the ground reference plane enables the formation of one less thin film layer than structures that form the ground reference plane in the thin film interconnect portion of the packaging structure.

The description above is intended to help illustrate the principles of this invention and is not intended to limit the scope of this invention in any way. Also, while the invention has been described with reference to a specific example thereof, it will be apparent to a person of ordinary skill in the art that various changes and modifications can be made to the concepts presented herein without departing from the spirit and scope of the invention. For example, while the invention was described with respect to removing a single portion of substrate 110 in which a single integrated circuit die can be attached, multiple portions of the substrate can be removed to attach multiple die 130A and 130B as shown in FIG. 5C. These equivalents and alternatives are intended to be included within the scope of the present invention.

What is claimed is:

1. A package for mounting an integrated circuit die, the package comprising:
a metal substrate having first and second opposing primary surfaces and an aperture formed therebetween; and
a flexible thin film interconnect structure formed over the first surface of the metal substrate and over the aperture, the flexible thin film interconnect structure comprising bottom and top opposing surfaces, the bottom surface including a first region in direct contact with the first surface of the metal substrate and a second region opposite the aperture, the second region comprising a first plurality of bonding pads exposed within the aperture, the first plurality of bonding pads having a first pitch appropriate for attaching the integrated circuit die to package, the top surface including a second plurality of exposed bonding pads having a pitch greater than the first pitch.

2. The package set forth in claim 1 wherein the flexible thin film interconnect structure comprises at least one thin film dielectric layer having an elongation percentage of at least 30 percent.

3. The package set forth in claim 1 wherein the flexible thin film interconnect structure comprises a plurality of thin film dielectric layers having an elongation percentage of at least 30 percent.

4. The package set forth in claim 1 wherein the flexible thin film interconnect structure comprises a plurality of thin film dielectric layers having an elongation percentage of between 40-50 percent.

5. The package set forth in claim 1 wherein a sidewall defining the aperture is angled or curved inward where the sidewall contacts the overlying flexible thin film interconnect structure.

6. The package set forth in claim 1 wherein the first plurality of bonding pads are flip chip pads.

7. The package set forth in claim 1 wherein the second plurality of bonding pads are ball grid array pads.

8. The package set forth in claim 1 further comprising an integrated circuit die positioned within the aperture and attached to the first plurality of bonding pads.

9. The package set forth in claim 8 further comprising a lid attached to the second surface of the metal substrate such that the lid encloses the integrated circuit die within the aperture.

10. The package set forth in claim 1 wherein the metal substrate is a copper substrate.

11. A package for mounting an integrated circuit die, the package comprising:
a metal substrate having first and second opposing primary surfaces and an aperture formed therebetween; and
a flexible thin film interconnect structure formed over the first surface of the metal substrate and over the aperture, the flexible thin film interconnect structure comprising bottom and top opposing surfaces and a plurality of thin film conductive layers and a plurality of thin film dielectric layers having an elongation percentage of at least 30 percent formed between the bottom and top surfaces, the bottom surface including a first region in direct contact with the first surface of the metal substrate and a second region that overlies the aperture, the second region comprising a plurality of flip chip bonding pads exposed within the aperture, the top surface of the flexible thin film interconnect structure including a plurality of exposed ball grid array bonding pads;
wherein the plurality of flip chip bonding pads have a pitch appropriate for attaching the integrated circuit die to package and the plurality of exposed ball grid array bonding pads have a pitch greater than the pitch of the plurality of flip chip bonding pads.

12. The package set forth in claim 11 further comprising an integrated circuit die attached to the plurality of flip chip bonding pads within the aperture.

13. The package set forth in claim 12 further comprising a lid attached to the second surface of the metal substrate such that the lid encloses the integrated circuit die within the aperture.

14. The package set forth in claim 13 wherein the metal substrate is a copper substrate.

15. The package set forth in claim 14 wherein the copper substrate has a thickness that is approximately equal to a combined thickness of the integrated circuit die and bumps.

16. A semiconductor device comprising:
a metal substrate having first and second opposing surfaces and an aperture formed therebetween;
a flexible thin film interconnect structure formed over the first surface of the metal substrate and over the aperture, the flexible thin film interconnect structure comprising bottom and top opposing surfaces and a plurality of thin film conductive layers and a plurality of thin film dielectric layers having an elongation percentage of at least 30 percent formed between the bottom and top surfaces, the bottom surface including a first region in direct contact with the first surface of the metal substrate and a second region that overlies the aperture;
a first plurality of bonding pads formed on the bottom surface of the thin film interconnect structure within the aperture of the metal substrate, the first plurality of bonding pads being spaced at an integrated circuit pitch;
a second of bonding pads formed on the top surface of the thin film interconnect structure, the second plurality of bonding pads being spaced at a package pitch;
a integrated circuit die integrated circuit die attached to the first plurality of bonding pads within the aperture; and
a lid attached to the second surface of the metal substrate such that the lid encloses the integrated circuit die within the aperture.

17. The semiconductor device set forth in claim 16 wherein the metal substrate is a copper substrate.

18. The semiconductor device set forth in claim 17 further comprising thermal grease between the integrated circuit die and the lid.

19. The semiconductor device set forth in claim 17 further comprising an underfill resin arranged between the integrated circuit die and the thin film interconnect structure.

20. The semiconductor device set forth in claim 17 further comprising contacts between the copper substrate and the thin film interconnect structure enabling the copper substrate to be used as a ground reference plane.
